(19) United States
(12) Patent Application Publication
(10) Pub. No.: US 2002/0060580 A1
(43) Pub. Date: May 23, 2002

(54) Probe card

(76) Inventor: Morihiro Yamabe, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/990,426

(22) Filed: Nov. 21, 2001

(30) Foreign Application Priority Data
Nov. 22, 2000 (JP) 2000-356664

(51) Int. Cl. G01R 31/02

(52) U.S. Cl. 324/754; 324/761

(57) ABSTRACT

There is provided a probe card comprising a plurality of contact pins to be in contact and connected with testing electrodes of semiconductor chips, implanted in the surface of a wiring board, for testing electrical characteristic of the semiconductor chips, wherein the contact pins have a micro-spring structure. With such a probe card as described, the contact pins can be arranged at a narrow pitch, and are caused to be in stable contact with the respective testing electrodes by sufficiently absorbing variation in the height of the respective testing electrodes, thereby enabling high-speed transmission of signals to be realized.

### BACKGROUND OF THE INVENTION

1. Field of the Invention

The present invention relates to a probe card to be connected with testing electrodes of semiconductor chips for testing the electric characteristics of the semiconductor chips.

2. Description of the Related Art

Dramatic advances in miniaturization and reduction in the cost of electronic equipment with semiconductor integrated circuits (hereinafter referred to as devices) mounted therein have been seen in recent years, and a demand for miniaturization and reduction in the cost of the devices has since grown very strong. Further, following the strong demand for the miniaturization, a form in which the devices are supplied has also changed. The devices are normally supplied in a form wherein semiconductor chips in a state as cut-out from a wafer are connected to lead frames by wire bonding, and subsequently, are sealed with plastic or ceramics.

However, upon development of a technology whereby the devices in a state (hereinafter, this state is referred to as a bare chip) of semiconductor chips as cut-out from a semiconductor wafer are mounted directly on a printed circuit board for the miniaturization of electronic equipment, there has since been a mounting demand for supply of the devices in a bare chip state at low cost. In order to provide quality assurance in supplying the devices in the bare chip state, it is necessary to conduct all tests in a semiconductor wafer state. That is, it becomes necessary to conduct a burn-in test and max. speed operation test on the semiconductor chips in the semiconductor wafer state.

In the normal process of testing the devices, defective semiconductor chips due to poor workmanship are screened through a DC test and a low-speed function test conducted by use of a semiconductor testing system (hereinafter referred to as a IC tester) in combination with a wafer prober during a wafer test as a pre-assembly process test, and semiconductor chips having teething troubles are screened through a burn-in test conducted by use of a semiconductor burn-in testing system (hereinafter referred to as TBT), as a post-wafer process test conducted after the devices are finished up in the final form thereof as packaged with plastic or ceramics. Thereafter, performance selection of conforming devices is carried out by conducting a high-speed function test (selection test) by use of the IC tester.

However, for supplying the devices in the bare chip state, there is the need for bringing forward all the burn-in test and the selection test which are conducted as the post-wafer process test to a step of testing the devices in the semiconductor wafer state (the normal pre-assembly process test). There has already been developed a wafer level burn-in system (hereinafter referred to as WLTBT) as a system for conducting the burn-in test in the semiconductor wafer state, adopting a method whereby a probe card (hereinafter referred to as a probe card for WLTBT) for transmitting test signals from the system to the testing electrodes of the respective semiconductor chips on the semiconductor wafer can contact all the testing electrodes en bloc of all the semiconductor chips on the wafer, and for the probe card, a membrane type is mainly employed.

As for a probe card (hereinafter referred to as a probe card for the IC tester) for transmitting test signals of the IC tester to the respective testing electrodes of the semiconductor chips on the semiconductor wafer, there have since been developed various types. The conventional types of the probe cards described above are broadly classified into the following three types. These are three types including a cantilever type, a vertical needle type, and a membrane type. The type in the most widespread use at present is the cantilever type which is a type wherein terminals formed from lengths of needle-like metal (such as tungsten, and so forth), and configured in a shape bent obtusely at a part thereof, close to the contact end side of the testing electrodes, are slantingly connected and fixed to a printed circuit board for the probe card. The cantilever type is capable of easily coping with an array at a narrow pitch, however, it has drawbacks in that surface disposition thereof in a wide area is very difficult to implement, and because the terminals are long in length, it has poor electric characteristics, having difficulty in speeding up operation.

The vertical needle type is a type of probe card with needle-like terminals erected vertically, having a construction so as to retain the tip of the respective terminals in holes defined in a ceramic material, and so forth. Accordingly, with the vertical needle type, it is easy to implement the surface disposition thereof in a wide area as well as speed-up in operation, however, it is difficult to narrow down a pitch due to limitations of fine patterning on ceramics. The membrane type is a type of probe card wherein bumps are formed on an insulation film, and contact pressure to which the respective bumps are subjected is borne by an elastic material sheet, disposed on the back face of the insulation film, and an electric signal to the respective bumps is transmitted to respective pads of a printed wiring board disposed on the backmost face of the insulation film via an electrically conductive material inside the elastic material sheet. With the membrane type, it is easy to cope with the surface disposition thereof in a wide area, speed-up in operation, and narrowing-down of a pitch, however, the membrane type has a drawback in that it is difficult to follow up variation in the height of the testing electrodes.

Now, all the aforementioned probe cards have both merits and demerits, and there is available no probe card satisfying all the needs for surface disposition, speed-up in operation, narrowing-down of the pitch, and capability of following up variation in the height. However, in view of rapid advances taking place at present in respect of miniaturization, speed-up in operation, and an increase in the number of pins of the semiconductor chips, there has since been a mounting demand for a probe card having all the merits described in the foregoing.

The present invention has been developed to solve the problems described above, and it is therefore an object of the present invention to provide a probe card capable of surface disposition at a narrow pitch, achieving stable contact of all contact pins with the respective testing electrodes by sufficiently absorbing variation in the height of the testing electrodes, and realizing high-speed transmission of signals.

### SUMMARY OF THE INVENTION

To this end, in accordance with a first aspect of the invention, there is provided a probe card comprising a plurality of contact pins to be in contact and connected with testing electrodes of semiconductor chips, implanted in the surface of a wiring board, for testing electrical characteristic of the semiconductor chips, wherein the contact pins have a micro-spring structure.

With the probe card described above, the contact pins are preferably installed by soldering so as to stand erect on respective pads formed on the surface of the wiring board.

Further, the contact pins each may comprise an extremity for contact with an electrode, to be in contact and connected with the respective testing electrodes, a S-shaped micro-spring section connected with the extremity for contact with the electrode so as to be aligned in a line therewith, and a soldering mount provided at one end of the S-shaped micro-spring section.

Still further, the contact pins each may comprise an extremity for contact with an electrode, to be in contact and connected with the respective testing electrodes, a folded-type micro-spring section connected with the extremity for contact with the electrode so as to be aligned in a line therewith, and a soldering mount provided at one end of the folded-type micro-spring section.

Yet further, soldering reinforcing grooves for reinforcing bonding by solder are preferably formed on the face of the respective soldering mounts, in contact with the respective pads.

Further, the contact pins are preferably plated with gold.

Still further, the contact pins may be formed of a nickel based metal.

Furthermore, the wiring board may be a ceramic multilayer board.

### BRIEF DESCRIPTION OF THE DRAWINGS

FIG. 1 is a perspective view showing an overall constitution of an embodiment of a probe card according to the invention;

FIG. 2(A) is a front elevation and

FIG. 2(B) is a side view, both showing the shape of a S-shaped contact pin according to the embodiment of the invention;

FIG. 3(A) is a perspective view showing a constitution of a probe card employing the S-shaped contact pin according to the embodiment of the invention, and

FIG. 3(B) is a plan view showing dimensions of an electrode pad and a soldering mount;

FIG. 4 is a plan view showing arrays of testing electrodes to which the embodiment of the invention is applied;

FIG. 5 is a plan view showing a procedure of soldering the contact pin in carrying out the embodiment of the invention;

FIG. 6(A) is a front elevation and

FIG. 6(B) is a side view, both showing the shape of a folded-type contact pin according to the embodiment of the invention;

FIG. 7 is a plan view showing arrays of testing electrodes to which the embodiment of the invention is applied;

FIG. 8(A) is a plan view showing arrays of testing electrodes to which the embodiment of the invention is applied,

FIG. 8(B) a plan view showing dimensions of an electrode pad and a soldering mount, and

FIG. 8(C) a front elevation showing a soldered state of the folded-type contact pin;

FIG. 9(A) is a front elevation, and

FIG. 9(B) is a side view, both showing the dimensions and shape of a specific example of the S-shaped contact pin according to the embodiment of the invention while

FIG. 9(C) is a plan view showing soldering reinforcing grooves; and

FIG. 10(A) is a front elevation, and

FIG. 10(B) is a side view, both showing the dimensions and shape of a specific example of the folded-type contact pin according to the embodiment of the invention while

FIG. 10(C) is a plan view showing soldering reinforcing grooves.

### DESCRIPTION OF THE PREFERRED EMBODIMENTS

An embodiment of a probe card according to the invention is described in detail hereinafter with reference to the accompanying drawings.

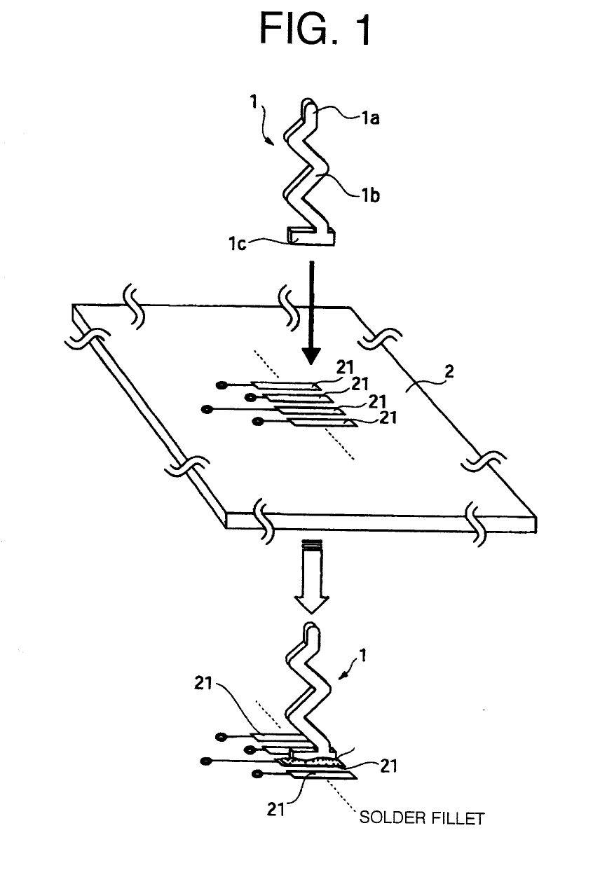

FIG. 1 is a view showing an overall constitution of the embodiment of a probe card according to the invention. As shown in the figure, the probe card comprises a plurality of contact pins 1 installed by soldering on the surface of a hyperfine-pitch ceramic multilayer wiring board 2 (wiring board) in such a way as to stand erect. Further, the contact pins 1 each comprise an extremity 1a for contact, to be in contact and connected with respective testing electrodes formed on respective semiconductor chips, a micro-spring section 1b connected with the extremity 1a for contact with the electrode so as to be aligned in a line therewith and configured in a zigzag shape, and a soldering mount 1c provided at one end (on the side of the micro-spring section 1b, opposite from the extremity 1a for contact with the electrode) of the micro-spring section 1b.

The contact pin 1 configured in such a shape as described above is made up of an electrically conductive metal shaped with high precision in dimensions by the metal precipitation method (additive method) taking advantage of techniques of, for example, photolithography or X-ray lithography. Examples of the electrically conductive metal include a nickel based metal such as pure nickel, a nickel alloy, and so forth. Further, the entire surface of the contact pin 1 is plated with gold in order to lower contact resistance.

The hyperfine-pitch ceramic multilayer wiring board 2 is provided with a plurality of electrode pads 21 to which the soldering mount 1c is attached by soldering, formed on the surface thereof, and has a function for serving as an electric signal interface with a WLTBT or IC tester. The positions of the electrode pads 21 are set such that the extremities 1a for contact with the electrode can correspond to the testing electrodes formed on the respective semiconductor chips with high precision. Further, the contact pins 1 are soldered to the respective electrode pads 21 by laser irradiation heating using a solder paste or solder ball. With this embodiment of the invention, the hyperfine-pitch ceramic multilayer wiring board 2 undergoing minimum deformation due to thermal contraction, and so forth is used as the wiring board in order to ensure positioning of the contact pins 1 with high precision.

With the probe card having such a constitution as described above, when conducting a test with the hyperfine-pitch ceramic multilayer wiring board 2 disposed at a predetermined height above the respective semiconductor chips, and opposite thereto, since the contact pins 1 have each the micro-spring section 1b of a micro-spring structure, variation in the height of the testing electrodes on the respective semiconductor chips can be absorbed, thereby enabling the extremities 1a for contact with the electrode to come in contact with the respective testing electrodes with reliability. Further, because the probe card is constructed such that the contact pins 1 are fixed to the respective electrode pads 21 by soldering, the contact pins 1 can be replaced with ease, thus resulting in excellent serviceability.

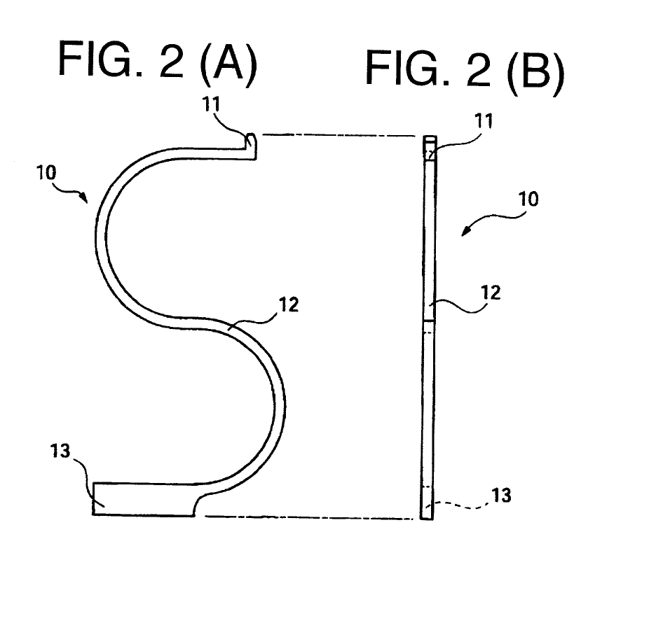

FIG. 2 is a view showing an example of a first modification (S-shaped contact pin 10) to the shape of the contact pins. As shown in the figure, the S-shaped contact pins 10 each comprise an extremity 11 for contact with the electrode, a S-shaped micro-spring section 12 connected with the extremity 11 for contact with the electrode so as to be aligned in a line therewith, and configured in a curved shape resembling the letter S, and a soldering mount 13 provided at one end of the S-shaped micro-spring section 12.

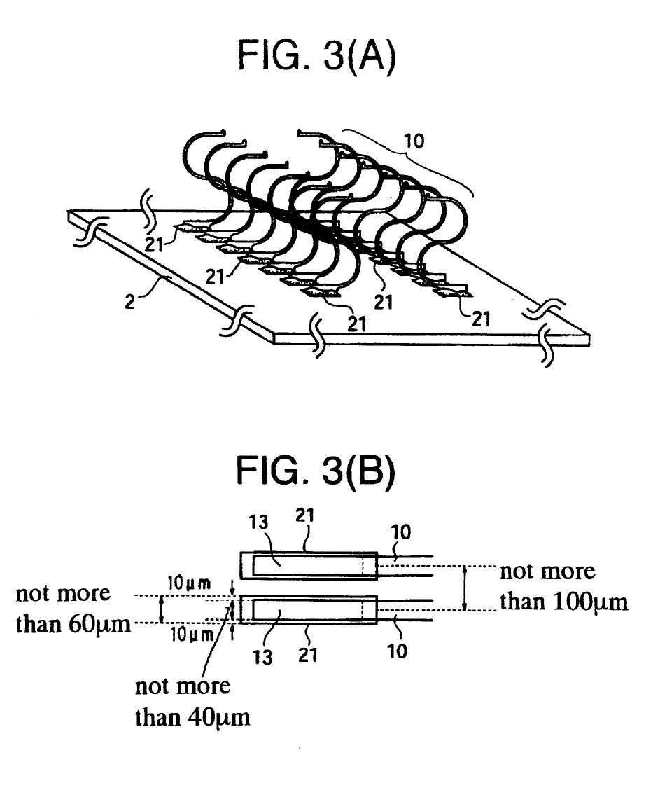

A plurality of the S-shaped contact pins 10 (more exactly, the soldering mounts 13) constituted as above are arranged as shown in FIG. 3 (A), and are bonded to the respective electrode pads 21 on the hyperfine-pitch ceramic multilayer wiring board 2 by soldering. As shown in FIG. 3 (B), the S-shaped contact pins 10 are arranged at an interval of, for example, not more than 100 μm, while the width of the respective electrode pads 21, in the direction in which the S-shaped contact pins 10 are arranged, is set at, for example, not more than 60 μm, and the width of the respective soldering mounts 13, in the same direction as described above, is also set at, for example, not more than 60 μm.

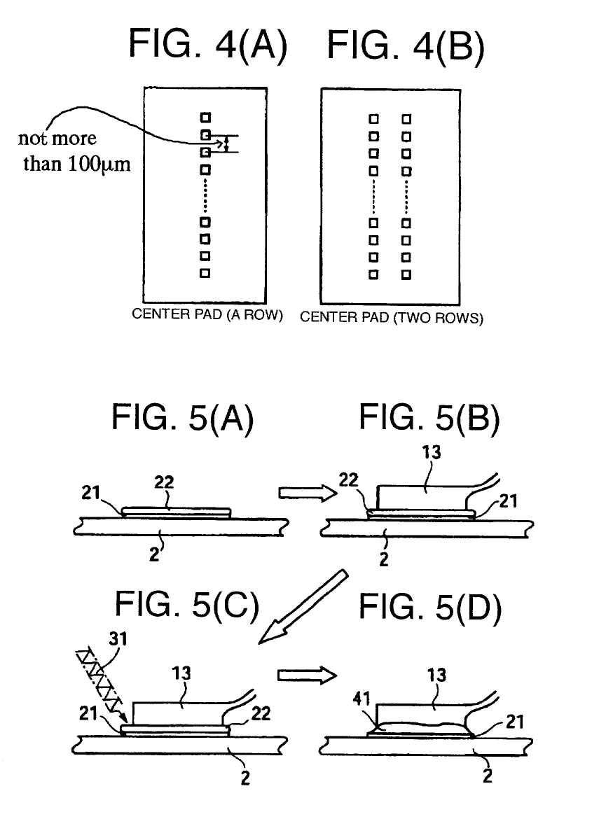

As shown in FIG. 4, there is a case where the testing electrodes on the semiconductor chips are arranged at a narrow pitch of, for example, not more than 100 μm, and lined up in a row or two rows. The probe card provided with the S-shaped contact pins 10 as previously described are able to cope with testing of the semiconductor chips with the testing electrodes disposed in such a way as described above.

Now, a method of soldering, adopted in carrying out the present embodiment, is described with reference to FIG. 5. As shown in FIG. 5(A), a solder paste 22 composed of fine particles, 5 to 10 μm in diameter, is first applied to the respective electrode pads 21 on the hyperfine-pitch ceramic multilayer wiring board 2 by use of a micro metal mask. Further, as shown in FIG. 5(B), the soldering mount 13 is disposed at a highly accurate position on top of the respective solder pastes 22 in such a way as to be in as-erect state.

In this state, a laser beam 31 having a spot diameter in the order of 100 μm is irradiated to both the respective solder pastes 22 and the respective soldering mounts 13 at the same time as shown in FIG. 5(C), whereupon solder is melted, and a fillet 41 is formed on both the respective electrode pads 21 and the respective soldering mounts 13, so that the respective soldering mounts 13 are bonded to the respective electrode pads 21 with solder as shown in FIG. 5(D).

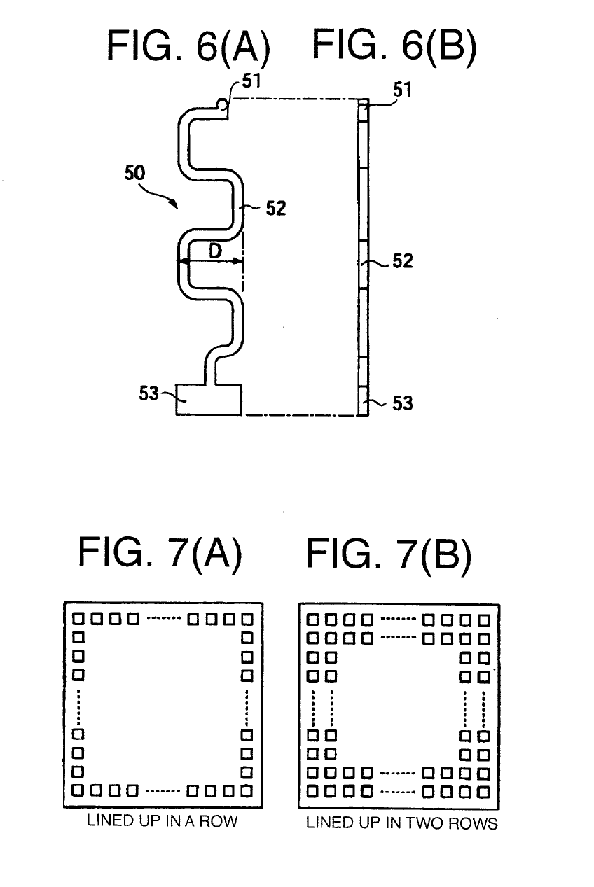

Now, referring to FIG. 6, an example of a second modification (folded-type contact pin 50) to the shape of the contact pins is described hereinafter. As shown in the figure, the folded-type contact pins 50 each comprise an extremity 51 for contact with the electrode, a folded-type micro-spring section 52 connected with the extremity 51 for contact with the electrode so as to be aligned in a line therewith, and configured in a folded shape, and a soldering mount 53 provided at one end of the folded-type micro-spring section 52.

Since the folded-type contact pin 50 has more folded points in comparison with curved points of the S-shaped contact pin 10, a width D of the former can be set smaller in size than that of the latter if it is intended that the former has elasticity identical to that of the latter. It follows therefore that the folded-type contact pins 50 can be disposed on the hyperfine-pitch ceramic multilayer wiring board 2 at a density higher than that in the case of the S-shaped contact pins 10.

A shown in FIG. 7, there is a case where the respective semiconductor chips are provided with the electrode pads 21 arranged at a narrow pitch, and lined up in a row or two rows in the two directions of X-Y on the periphery thereof. The folded-type contact pins 50 is able to cope with testing of such semiconductor chips as described above because the folded-type contact pins 50 can be disposed at a high density as described in the foregoing.

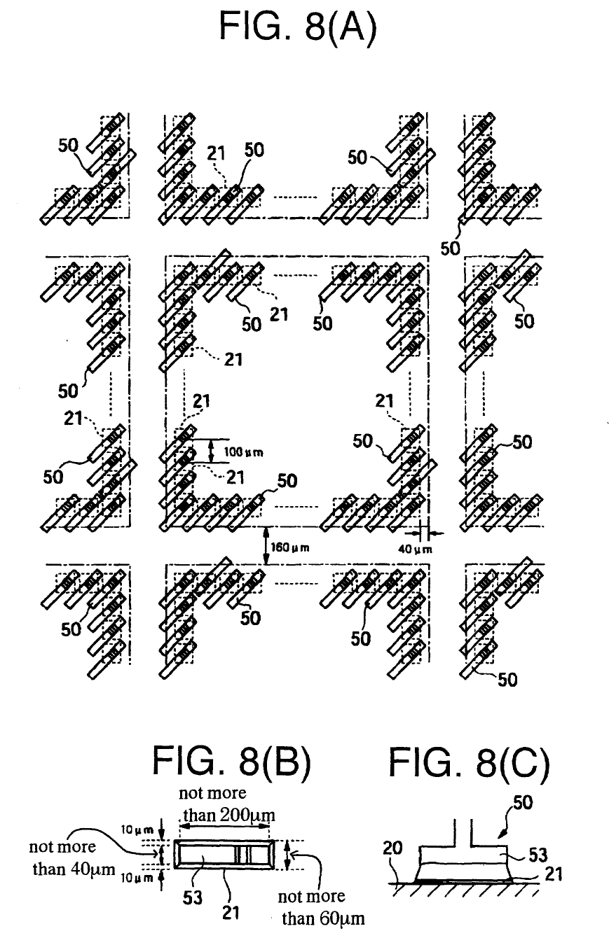

For example, in the case of testing the semiconductor chips provided with a plurality of the electrode pads 21 formed in such a state as arranged at a pitch not more than 100 μm and lined up in a row on the periphery of the respective semiconductor chips as shown in FIG. 8(A), it is possible to cope with the case by setting the total width of the soldering mount 53 to not more than 200 μm, and the thickness thereof to not more than 40 μm. In the case of the electrode pads 21 being lined up in two rows on the periphery of the respective semiconductor chips, it is necessary to design a shape thereof such that the soldering mount 53 is not more than 120 μm in the total width.

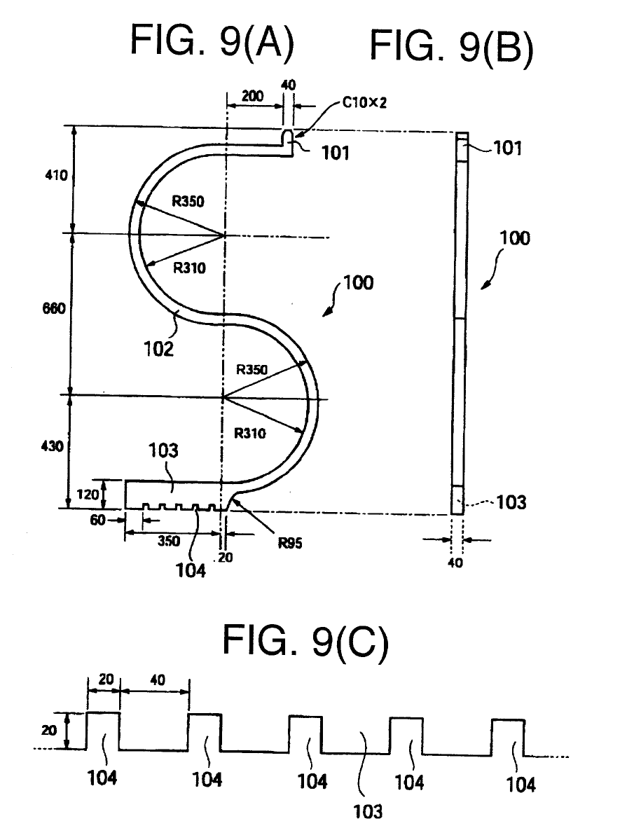

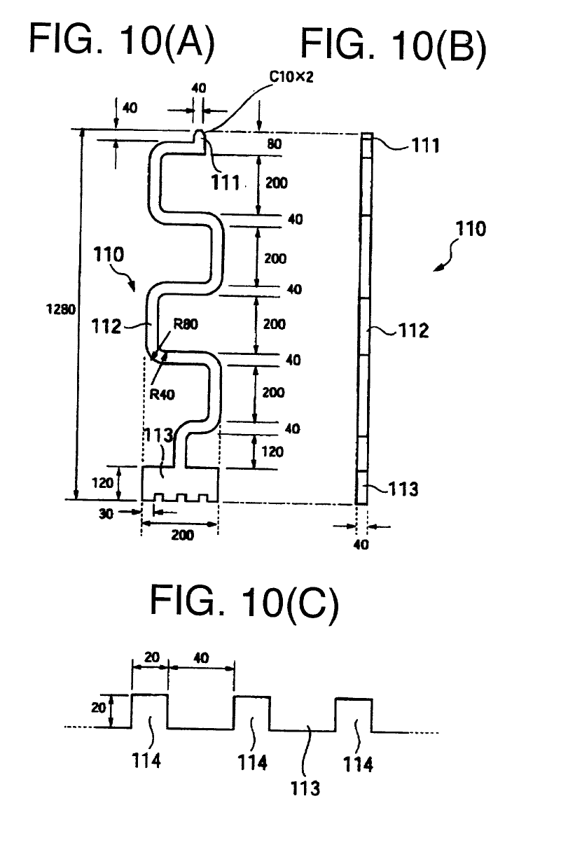

Further, the specific dimensions and shapes of the aforementioned S-shaped contact pin 10 and folded-type contact pin 50 are described hereinafter with reference to FIGS. 9 and 10. All figures in FIGS. 9 and 10 are expressed in a unit of μm (micrometer). FIG. 9 shows a specific example (S-shaped contact pin 100) of the S-shaped contact pin 10, and FIG. 10 shows a specific example (folded-type contact pin 110) of the folded-type contact pin 50.

As shown in FIG. 9, soldering reinforcing grooves 104 for reinforcing bonding by solder are additionally formed on a soldering mount 103 of the S-shaped contact pin 100. The dimensions of the soldering reinforcing grooves 104 are set at 20 μm in width and 20 μm in depth, and five of the soldering reinforcing grooves 104 are provided at a given interval. Soldering reinforcing grooves 114 for reinforcing bonding by solder are additionally formed on a soldering mount 113 of the folded-type contact pin 110 as well. The dimensions of the soldering reinforcing grooves 114 are set at 20 μm in width and 20 μm in depth, and three of the soldering reinforcing grooves 114 are provided at a given interval.

Both the S-shaped contact pin 100 and the folded-type contact pin 110 have respective extremities 101, 111, for contact with an electrode, which are deviated from the center axis thereof, and are set to be in a shape so as to allow the respective extremities 101, 111, for contact with the electrode to slip transversely accordingly as a load is imposed thereon when the S-shaped contact pin 100 and the folded-type contact pin 110 come in contact with the respective electrode pads 21. Further, the respective extremities 101, 111, for contact with the electrode are provided with edges chamfered at C 10 μm, respectively.

With the dimensions and shape, set as above, if the electrode pad 21 is, for example, an aluminum pad, an aluminum oxide film spontaneously formed on the surface of the aluminum pad is broken through as if scraped by the soldering mounts 103, 113, respectively, enabling proper electrical contact to be implemented In addition, because the length of the entire path of the S-shaped contact pin 100 and the folded-type contact pin 110, respectively, is set to be very short at not more than 2 mm, both the contact pins have excellent high frequency characteristic in transmission of electric signals.

As described hereinbefore, with the probe card according to the present invention, the respective contact pins can be caused to be in contact with the plurality of the testing electrodes arranged at a narrow pitch on the respective semiconductor chips with reliability by sufficiently absorbing variation in the height of the testing electrodes, and since the contact pins themselves are minute, and the entire path thereof is very short in length, high-speed transmission of signals can be achieved.

What is claimed is:

1. A probe card comprising a plurality of contact pins to be in contact and connected with testing electrodes of semiconductor chips, implanted in the surface of a wiring board, for testing electrical characteristic of the semiconductor chips, wherein the contact pins have a micro-spring structure.

2. A probe card according to claim 1, wherein the contact pins are installed by soldering so as to stand erect on respective pads formed on the surface of the wiring board.

3. A probe card according to claim 1 or claim 2, wherein the contact pins each comprise an extremity for contact with an electrode, to be in contact and connected with the respective testing electrodes, a S-shaped micro-spring section connected with the extremity for contact with the electrode so as to be aligned in a line therewith, and a soldering mount provided at one end of the S-shaped micro-spring section.

4. A probe card according to claim 1 or claim 2, wherein the contact pins each comprise an extremity for contact with an electrode, to be in contact and connected with the respective testing electrodes, a folded-type micro-spring section connected with the extremity for contact with the electrode so as to be aligned in a line therewith, and a soldering mount provided at one end of the folded-type micro-spring section.

5. A probe card as set forth in any of claims 1 to 4, wherein soldering reinforcing grooves for reinforcing bonding by solder are formed on the face of the respective soldering mounts, in contact with the respective pads.

6. A probe card as set forth in any of claims 1 to 5, wherein the contact pins are plated with gold.

7. A probe card as set forth in any of claims 1 to 6, wherein the contact pins are formed of a nickel based metal 8. A probe card as set forth in any of claims 1 to 7, wherein the wiring board is a ceramic multilayer board.
